(19) United States
(12) Patent Application Publication
(10) Pub. No.: US 2001/0055231 A1
(43) Pub. Date: Dec. 27, 2001

(54) Apparatus and method for detecting the temperature in a disk memory device

(76) Inventor: Kenji Tsuruta, Tokyo (JP)

Correspondence Address: PILLSBURY WINTHROP LLP, 1600 TYSONS BOULEVARD, MCLEAN, VA, 22102, US

(21) Appl. No.: 09/816,866

(22) Filed: Mar. 26, 2001

(30) Foreign Application Priority Data
Mar. 24, 2000 (JP) P2000-085101

(51) Int. Cl. G11C 7/00

(52) U.S. Cl. 365/202

(57) ABSTRACT

The apparatus and method for detecting the temperature in the disk memory device includes two voltage source dividing circuits. One of the voltage dividing circuits includes a first and second temperature independent resistances connected to the voltage source in series for providing a first electric potential from a connecting point located between the first and second resistances. The other voltage source dividing circuits includes a third temperature independent resistance and a temperature dependent resistance for detecting the temperature connected to the voltage source in series for providing a second electric potential from connecting point between the third temperature independent resistance and the temperature dependent resistance. The first and the second electric potentials are converted to an electric potential ratio. The temperature is acquired by referencing to a predetermined electric potential ratio-temperature characteristic based on the calculated electric potential ratio.

### BACKGROUND OF THE INVENTION

1. Field of the Invention

The present invention relates to devices that detect the environmental temperature in electronic equipment, such as disk memory devices, and more particularly, to an apparatus and method for accurately detecting the temperature in the equipment by employing a simple detecting mechanism.

2. Description of the Related Art

Typically, a magnetic disk device is used to store and reproduce the data downloaded to a data processing device, such as a personal computer (PC). In general, the magnetic disk device includes a temperature detecting circuit for detecting the environmental temperature in the magnetic disk device. Usually, it has been proposed to use a temperature detecting resistance element, such as a thermistor, in the temperature detecting circuit. Such a conventional temperature detecting technique uses the dispersions of the temperature coefficients of the thermistor. Thus, the thermistor detects different values at respective predetermined temperatures.

The conventional temperature detecting circuit includes a constant current source circuit, a thermistor element, a reference resistance element and an analog-to-digital converter (ADC). In order to supply a current to the thermistor element and the reference resistance element, the constant current source circuit is switched between each element. The ADC detects the difference between the thermistor and the reference resistance elements and corrects such differences in order to detect the temperature.

Thus, the conventional method needs to confirm the correcting values, which are obtained at two predetermined temperature points by changing the environmental temperature. Further, the conventional method requires a constant current source circuit. The conventional method mainly aims to correct dispersions of the detecting temperature due to the dispersions of the temperature coefficient of the thermistor.

Although recent improvements have increased the accuracy of the thermistor so that the thermistor's fluctuations do not exceed a maximum level of 2%, it has recently been noted that the fluctuations of the voltage source is the biggest cause of the dispersions for detecting the temperature. It has been discovered that the fluctuations of the voltage source may reach up to a maximum level of 10%.

Conventional techniques have been proposed in order to detect the temperature while mitigating the fluctuations of the voltage source.

These conventional techniques typically employ three voltage dividing circuits coupled to a voltage source in parallel. Thus, the temperature detecting mechanism includes a first series circuit that comprises a first resistance element and a thermistor, a second series circuit that comprises a second resistance element and a third resistance element having the same resistance value as the resistance value of the thermistor set at a predetermined first temperature, and a third series circuit that comprises a fourth resistance element and a fifth resistance element having the same resistance value as the resistance value of the thermistor set at a predetermined second temperature. At each of the connecting points of the first, second and third series circuits respectively, each of the detected electric potentials is converted into the respective digital values through an ADC. By calculating the resistance value of the thermistor based on each of the digital values, a temperature is determined from the calculated resistance value.

Thus, the conventional temperature detecting circuits require three voltage source dividing circuits. Further, it is very difficult to select the third and fourth resistance elements so that the third resistance element has the same resistance value as the resistance value of the thermistor at the first temperature and so that the fourth resistance element has the same resistance value as the resistance value of the thermistor at the second temperature.

Further, the conventional temperature detecting circuits aim to avoid fluctuations of the reference voltage of the ADC, as well as fluctuations of the voltage source. However, in comparison to the fluctuation of the voltage source, the fluctuation of the ADC reference voltage is too small. Therefore when the conventional devices are required to detect temperatures with an accuracy of, for example, +1° C., it can neglect such small fluctuations of the ADC reference voltage for a temperature detecting circuit.

Thus, the first conventional apparatus and method for detecting temperature require a constant current source circuit, and the second conventional apparatus and method for detecting temperature require three series circuits for dividing the voltage source. Further, there are restrictions for selecting the resistance values of the resistance elements of the series circuits. Accordingly, the conventional apparatus and method for detecting temperature suffer from serious shortcomings.

### SUMMARY OF THE INVENTION

Therefore, there is a need for a device and method to perform a reliable temperature detection in a disk memory device employing a simplified temperature detecting mechanism and method.

An apparatus and method for detecting temperature according to the invention solve the aforementioned problems and defects of a conventional apparatus and method. Namely, the object of the present invention is to provide a novel apparatus and method to perform reliable temperature detection in electronic equipment, such as a disk memory device, by using a simplified temperature detecting construction.

In order to achieve the above-mentioned objectives, the apparatus for detecting the temperature in a disk memory device according to the invention may perform the temperature detection with high accuracy by simply using a pair of voltage source dividing circuits. The apparatus for detecting the temperature in equipment according to the invention includes a first voltage source dividing circuit including a first and second resistance connected in series and a second voltage source dividing circuit including a third resistance and a temperature detecting resistance connected in series.

The apparatus further includes an ADC for reading a first electric potential at a first connecting point between the first resistance and the second resistance in the first voltage source dividing circuit and a second electric potential at a second connecting point between the third resistance and the temperature detecting resistance in the second voltage source dividing circuit in order to calculate an electric potential ratio between the first electric potential and the second electric potential. The apparatus also includes an electric potential ratio/temperature converting mechanism for acquiring a temperature corresponding to the calculated electric potential ratio by referencing to a predetermined electric potential ratio-temperature characteristic.

In the construction of the apparatus, the electric potential ratio obtained from the first electric potential and the second electric potential is decided by the resistance values of the three temperature independent resistances, i.e., the first to third resistances and the resistance value of the temperature detecting resistance. Accordingly, it becomes possible to decide preliminarily the electric potential ratio—temperature characteristic. Further, the apparatus can avoid the influences due to the fluctuations of the voltage source since the electric potential ratio does not include any element of the voltage source.

Thus, the apparatus according to the invention can accurately detect temperatures in the device based upon the electric potential ratio and the predetermined electric potential ratio—temperature characteristic while avoiding the influences due to the fluctuation of the voltage source.

The apparatus may store the electric potential ratio—temperature conversion in a data form in a table in a non-volatile memory in order to obtain an temperature by simply referencing the conversion table.

By installing the temperature detecting apparatus in a disk memory device, it becomes possible to change the various temperature dependent control conditions in the device by using the detected temperature in order to maintain the conditions at an optimum (peak) position.

The apparatus according to the invention may include an ADC installed in a CPU, which controls the entire operations of the disk memory device. Further, the CPU may perform the calculation of the electric potential ratio and the conversion of the electric potential ratio to the temperature.

Further, the apparatus may store the electric potential ratio-temperature conversion into a table within a non-volatile memory that usually stores the control programs for the disk memory device.

Still further, the method for detecting the temperature is applicable to an equipment that comprises a CPU for controlling the operations of the equipment, a first voltage source dividing circuit including a first and a second temperature independent resistances connected to a voltage source in series, a second voltage source dividing circuit including a third temperature independent resistance and a temperature dependent resistance connected to the voltage source in series in order to detect the temperature.

The method includes the steps of reading a first electric potential at a first connecting point positioned between the first and second temperature dependent resistances in the first voltage source dividing circuit and a second electric potential at a second connecting point positioned between the third resistance element and the temperature detecting resistance in the second voltage source dividing circuit; converting the first and second electric potentials into a respective digital value; calculating an electric potential ratio between the first electric potential and the second electric potential by using the converted digital values; and acquiring a temperature in response to the calculated electric potential ratio by referencing to a predetermined electric potential ratio-temperature characteristic.

Additional objects and advantages of the invention will be set forth in the description that follows and in part will be obvious from the description, or may be learned by practicing the invention. The objects and advantages of the invention may be realized and obtained be means of the instrumentalities and combinations particularly pointed out in the appended claims.

### BRIEF DESCRIPTION OF THE DRAWINGS

A more complete appreciation of the present invention and many of the attendant advantages thereof will be obtained as the same becomes better understood by reference to the following detailed description when considered in connection with the accompanying the drawings.

FIG. 1 is a block diagram illustrating components of a magnetic disk device applicable to an apparatus and method for detecting temperatures according to the invention.

FIG. 2 is an example of the data constructions in the electric potential ratio-temperature conversion table shown in FIG. 1.

### DESCRIPTION OF THE PREFERRED EMBODIMENTS

Reference will now be made in detail to the preferred embodiments of the present invention, examples of which are illustrated in the accompanying drawings.

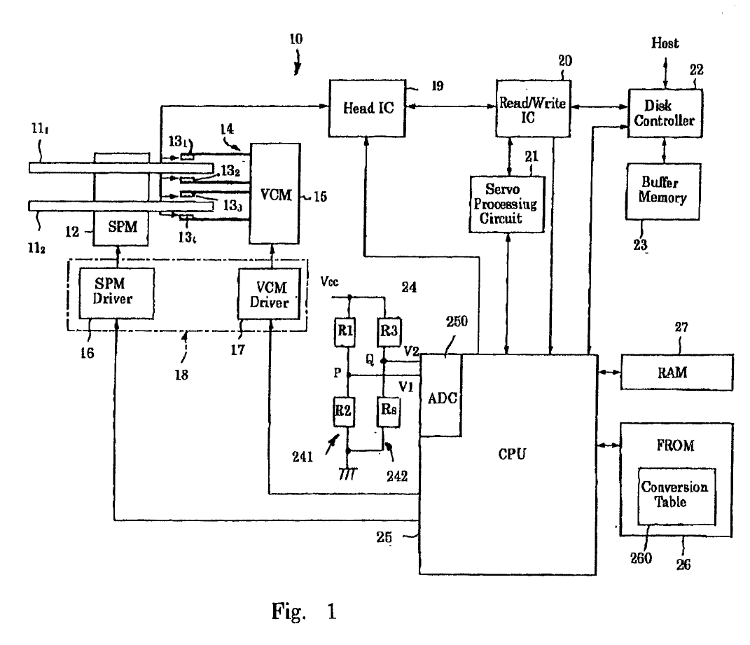

As illustrated in FIG. 1, a magnetic disk device (HDD) 10, which is an applicable apparatus and method for detecting temperatures consistent with the invention, includes at least one magnetic disk 11 for recording data, a spindle motor (SPM) 12 for driving the magnetic disk 11 at a high rotation speed, a magnetic head 13 for writing/reproducing data to the magnetic disk 11, a rotary actuator 14 for supporting the magnetic head 13 and a voice coil motor (VCM) 15 for driving the rotary actuator 14 to load and unload the magnetic head 13 to and from a ramp block (not shown).

For the purpose of simplifying the disclosure, FIG. 1 illustrates two disk medium 11₁ and 11₂ stacked along the spindle motor (SPM) 12. But, of course, it is also possible to apply an apparatus and method consistent with the present invention to a disk device including more than two disk mediums are stacked along the SPM or a disk device including only a single disk medium.

In order to read or write data on the recording tracks, each of the magnetic heads 13₁, 13₂, 13₃, 13₄ travels very close to each of the recording surfaces of the disk medium 11₁ and 11₂, respectively.

Each of the recording surfaces of the disk medium, includes a plurality of concentric recording tracks (not shown) for recording servo data and user data. The servo data is used to determine a head position on the tracks so that a reading/writing operation can be performed. Each of the recording tracks includes its servo area disposed at a predetermined interval. The area positioned between the two servo areas serves as a user data sector.

Each of the magnetic heads 13 attaches to a suspension arm of the rotary actuator 14. The rotary end of the actuator 14 is magnetically coupled to the voice coil motor (VCM) 15 to load and unload the head 13. Angular rotation of the head actuator (VCM) 15 along a radius direction of the disk 11 executes the loading/unloading of the magnetic head 13.

The rotation of the SPM 18 is executed by supplying the SPM driving currents (SPM currents) from a SPM driver (driving circuit) 16. The angular rotation of the head actuator (VCM) 15 is executed by supplying the VCM driving currents (VCM currents) from a VCM driver (head actuator driving circuit) 17. In this embodiment, the SPM driver 16 and the VCM driver 17 are provided as a driver IC 18 of a one-chipped integrated circuit. The amount of the driving current for the SPM 12 and the VCM 15 supplied from the SPM driver 16 and the VCM driver 17, respectively, is determined by a central processing unit (CPU) 25.

In order to locate the head position over a target track of the disk 11, the suspension arm of the actuator 14 moves in an inward circular direction toward the disk medium 11 in accordance with the angle rotation of the actuator 14. After deciding the head position, the head 13 scans over the target track of the disk reading the servo data and reading/writing data into the target sector between the target servo areas.

Each of the magnetic heads 13₁, 13₂, 13₃, 13₄ connects to a head amplifier circuit (head IC) 19 that mounts in a flexible printed circuit board (FPC). The head IC 19 controls the switching among the plurality of heads and also controls the input/output of the read/write signals for the heads 13₁, 13₂, 13₃, 13₄ under the control of the CPU 25. Further, the head IC 19 amplifies the analog output signals (head reading signal) from the respective heads 13₁, 13₂, 13₃, 13₄ and also executes a predetermined signal processing of write data, which is transferred from a read/write IC (read/write circuit) 20.

The read/write IC 20 includes a plurality of functions. For instance, the read/write IC 20 includes an automatic gain control (AGC) function for amplifying the head read signal supplied from the head IC 19 to a predetermined voltage and a decoding function (read channel) for processing the read signal in order to decode the read signal into, for example, a Non Return-to Zero (NRZ) code. The read/write IC 20 further includes an encoding function (write channel) for processing the data in order to record on the disk 11, a pulsing function for outputting the read signal as pulsed read data in order to extract the servo data from the read signal, and a burst data extracting function from the servo data in accordance with the burst timing signal supplied from a servo processing circuit 21. The burst data is transmitted to the CPU 25 in order to control the positioning of the head 13 for each target track on the disk 11.

The servo processing circuit 21 includes a timing signal generating function for generating various timing signals that include a burst timing signal for obtaining servo data among the read pulses outputted from the read/write IC 20, and an extracting function of cylinder code among the servo data. The extracted cylinder code is supplied to the CPU 25 in order to locate the positioning control of the head 13 over the target track on the disk 11.

Each of the read/write IC 20 and the CPU 25 is respectively coupled to host electronic equipment (Host), such as a personal computer (PC) through a disk controller 22. Thus, the disk controller 22 has a interface function for controlling the communication of the commands, such as the write commands and read commands, for transmitting data to and from the host equipment and a buffer controlling function for a buffer memory 23 that is connected to the disk controller 22.

The buffer memory 23 is mainly used as a write cache for temporarily storing the write data transferred from the host for writing in order to be recorded onto the disk 11 and also used for a read cache for temporarily storing the data read from the disk 11 in order to be transferred to the host. The buffer memory 23 is constructed by using, for example, a random access memory (RAM).

The CPU 25 executes the entire operations of the HDD based on the control programs, such as a head positioning control based on both the cylinder code extracted from the servo processing circuit 21 and the burst data extracted from the read/write IC 20, and a read/write access control of the disk by the disk controller 22 in accordance with the read/write commands supplied from the host.

The CPU 25 includes an ADC 250 for converting electric potentials from a voltage diving circuit 24 into digital values. As illustrated in FIG. 1, the voltage diving circuit 24 comprises a couple of voltage dividing circuits 241, 242 for dividing a voltage source Vcc. Thus, as an example of the invention, a first voltage dividing circuits 241 and a second voltage dividing circuits 242 are connected in parallel between a first terminal of the voltage source Vcc and a second terminal which is grounded. But, of course, it is possible to provide the voltage diving circuit 24 between a positive voltage source terminal as the first power terminal and a negative voltage source terminal as the second power terminal.

The first voltage dividing circuits 241 comprises a first resistance R1 and a second resistance R2 that are connected in series. One end of the first resistance R1 connects to the first power terminal of the voltage source Vcc and one end of the second resistance R2 connects to the second power terminal which is grounded. Thus, the first resistance R1 and the second resistance R2 constitute a series circuit between the voltage source Vcc and the ground.

The second voltage dividing circuits 242 comprises a third resistance R3 and a temperature detecting resistance Rs, such as a thermistor, which are connected in series. One end of the third resistance R3 connects to the first power terminal of the voltage source Vcc, and one end of the temperature detecting resistance Rs connects to the second power terminal, which is grounded. Thus, the third resistance R8 and the temperature detecting resistance Rs form a series circuit between the voltage source Vcc and the ground.

In order to simplify the explanation of the invention, this example will suppose that each of the resistances has a respective resistance values the same as the reference numbers of R1, R2, R3 and Rs. As it is well known, the resistance value Rs for the temperature detecting resistance varies in accordance with the temperature.

As illustrated in FIG. 1, one terminal of the ADC 250 connects to a first connecting point P between the first resistance R1 and the second resistance R2 of the first voltage dividing circuit 241. The other terminal of the ADC 250 connects to a second connecting point Q between the third resistance R3 and the temperature detecting resistance Rs of the second voltage dividing circuit 242. The electric potential value at the first connecting point P of the first voltage dividing circuit 241 is represented as V1, and the electric potential value at the second connecting point Q for the second voltage dividing circuit 242 is represented as V2.

The ADC 250 reads each of the electric potentials V1 and V2 at the respective connecting points P and Q for the respective first and second voltage dividing circuit 241 and 242 and converts the electric potentials VI and V2 to their respective digital values. Using the digital values, the CPU 25 calculates an electric potential ratio of V2/V1. As will be explained below, the electric potential ratio V2/V1 is used for detecting the temperature of the HDD with reference to the electric potential ratio—temperature conversion table 260. The detected temperature is used for determining the amount of writing current to be supplied to the writing head 13.

The CPU 25 connects to a Flash Read Only Memory (FROM) 26 of a nonvolatile memory, which preliminarily stores the control program, and the CPU 25 connects to a random access memory (RAM) 27, which supplies the work area for the CPU 25. But, of course, it is possible to build the FROM 26 and the RAM 27 into the CPU 26.

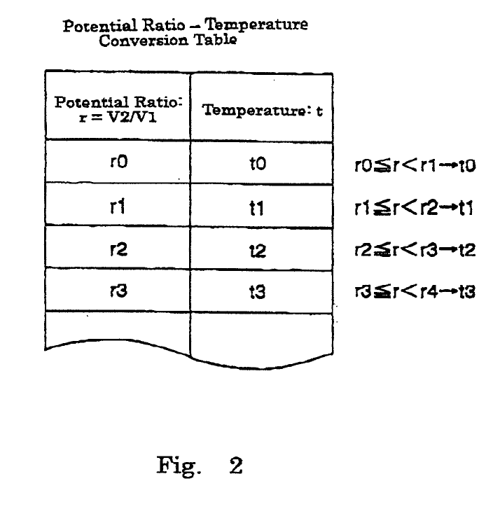

As explained above, the electric potential ratio—temperature conversion table 260 is preliminarily stored in the FROM 26. The electric potential ratio—temperature conversion table 260 shows a relationship between the various values of the electric potential ratio of V2/V1 and the temperature corresponding to each of the electric potential ratio, as shown in FIG. 2.

In the conversion table of FIG. 2, the temperatures t0, t1, t2, t3, among the continuous entry, increases, for example, by 1° C.

The following explains the method for detecting the temperature using the voltage detecting circuit 24 applicable to a magnetic disk device 10 as illustrated in FIG. 1.

First, the voltage source Vcc for the disk device is divided into a ratio between the resistance value R1 and the resistance value R2 for the first voltage dividing circuit 241 in the voltage detecting circuit 24. Thus, the electric potential V1 at the connecting point P between the first resistance R1 and the second resistance R2 is determined as shown in the following equation (1):

V1=[R2/(R1+R2)]·Vcc (1)

Further, the voltage source Vcc is divided into a ratio between the resistance value R3 and the resistance value Rs for the second voltage dividing circuit 242 in the voltage detecting circuit 24. Thus, the electric potential V2 at the connecting point Q between the third resistance R3 and the temperature detecting resistance Rs is determined as shown the following equation (2):

V2=[Rs/(R3+Rs)]·Vcc (2)

In order to detect the environmental temperature of the magnetic disk device, the CPU 25 reads the respective electric potentials V1 and V2 at the respective points P and Q and converts the potentials into digital values using the ADC 250.

The CPU 25 calculates the electric potential ratio V2/V1 by using the electric potentials V1 and V2 that are measured at the respective connecting points P and Q detected by the ADC 250. The ratio V2/V1 is represented as follows by using the above equations (1) and (2).

$$\begin{matrix}V 2 / V 1 = [ Rs / ( R 3 + Rs ) ] / [ R 2 / ( R 1 + R 2 ) ] \\ = [ Rs ( R 1 + R 2 ) ] / [ R 2 ( R 3 + Rs ) ]\end{matrix} \qquad ( 3 )$$

Here, there are no restrictions for the resistance values of the respective resistances R1, R2, and R3.

As is apparent from the above equation (3), the electric potential ratio V2/V1 represents a measured value that is not influenced by the fluctuations of the voltage source Vcc. Thus, the quotient includes resistance value Rs of the temperature detecting resistance. Since the resistance value RS is uniformly decided by the temperature, the electric potential ratio (r=V2/V1) also is a measured value that is uniformly decided by the temperature.

Consequently, the apparatus and method for detecting the temperature consistent with the invention is characterized in that each of the electric potential ratios r0, r1, r2, r3, - - - at each of the temperatures t0, t1, t2, t3 - - - is preliminarily calculated by using the temperature detecting resistance Rs and in order to produce an electric potential ratio—temperature conversion table 260, such as shown in FIG. 2. The produced electric potential ratio—temperature conversion table 260 is stored into the Flash ROM (FROM) 26 at a manufacturing stage of the magnetic disk device.

The CPU 25 calculates the electric potential ratio r by using the electric potentials read out at each of the connecting points P and Q through the use of the ADC 250. Further the CPU 25 searches the entries of the electric potential ratio—temperature conversion table 260 for the electric potential ratio r and the temperature. When the electric potential ratio r, calculated by the CPU 25, is located within a range rᵢ≦r<rᵢ₊₁, the corresponding temperature tᵢ to the electric potential ratio rᵢ is selected as the corresponding temperature for the electric potential ratio.

Accordingly, in the apparatus and method for detecting the temperature consistent with the invention, it is possible to detect the temperature accurately without the influences of the fluctuations of the voltage source Vcc by calculating the electric potential ratio r at the two connecting points in the voltage dividing circuit 24 and by referencing the electric potential ratio—temperature conversion table 260 based on the calculated electric potential ratio r.

Therefore, the CPU 25 may change the controlling conditions of the temperature dependent objects in the magnetic disk device in the most appropriate manner in accordance with the detected temperature.

For example, an overwrite characteristic for a magnetic disk device varies in accordance to the variation of the temperature in the magnetic disk device. Thus, due to its temperature dependent characteristic, the predetermined optimum value of a writing current that is supplied to a head is shifted from the optimum value when the temperature in the magnetic disk device varies.

In the apparatus and method consistent with the invention, such a peak shift due to the overwrite characteristic can be restrained by controlling the head IC 19 so as to obtain the optimum value for the writing current corresponding to the detected temperature with reference to the table stored in the FROM 28.

In order to obtain the optimum value for the writing current corresponding to the detected temperature, it is preferable to position the temperature detecting resistance Rs in the vicinity of the disk medium.

In this exemplary embodiment, the continuous entry in the electric potential ratio—temperature conversion table changes by 1° C. It is also possible to change the variance in the degree of accuracy in accordance to the required accuracy. Thus, for example, the accuracy may be changed to be 0.5° C. or 2° C.

Further, in the second voltage dividing circuit 242 of this embodiment illustrated in FIG. 1, the third resistance R3 connects to the voltage source side terminal and the temperature detecting resistance Rs connects to the ground voltage side terminal. However, it is possible to convert its connecting terminals for the third resistance RS and the temperature detecting resistance Rs.

In that case, the electric potential V2 at the connecting point Q between the temperature detecting resistance Rs and the resistance Rd becomes as follows:

V2={R3/(R3+Rs)}·Vcc (4)

Consequently, from the above equations (1) and (4), the electric potential ratio V2/V1 is represented as follows:

$$V 2 / V 1 \begin{matrix}= \{ R 3 / ( R 3 + Rs ) ] / \{ R 2 / ( R 1 + R 2 ) \} \\ = \{ R 3 ( R 1 + R 2 ) \} / \{ R 2 ( R 3 + Rs ) \}\end{matrix} \qquad ( 5 )$$

As explained above, the apparatus and method consistent with the invention can detect the temperature in the object device extremely accurately without the influences fluctuations of the voltage source.

Other embodiments of the present invention will be apparent to those skilled in the art consideration of the specification and practice of the invention disclosed herein. In particular, the invention is applicable to any types of equipment that needs to detect temperature in the device, such, for example, a light-magnetic disk device. It is intended that the specification and examples be considered as exemplary only, with a true scope and sprit of the invention being indicated by the following claims.

What is claimed is:

1. An apparatus for detecting temperature in an electronic equipment, comprising:
a CPU for controlling operations in the electronic equipment;
a first voltage source dividing circuit connected to a voltage source in series, the first voltage source dividing circuit comprising a first and a second elements having temperature-independent resistances;
a second voltage source dividing circuit connected to the voltage source in series, the second voltage source dividing circuit comprising a third element having temperature-independent resistance and a temperature detecting element having temperature-dependent resistance;
an analog-to-digital converter for reading a digital value of a first electric potential at a first connecting point between the first and the second elements in the first voltage source dividing circuit and a second electric potential at a second connecting point between the third element and the temperature detecting element in the second voltage source dividing circuits;
a calculation mechanism for calculating an electric potential ratio using the digital values detected by the ADC based on the first and the second electric potentials; and
an electric potential ratio/temperature converting mechanism for acquiring a temperature that corresponds to the electric potential ratio by referencing to a predetermined electric potential ratio-temperature characteristic.

2. The apparatus according to claim 1, further comprising;
a non-volatile memory for preliminary storing an electric potential ratio-temperature conversion table that shows the electric potential ratio-temperature characteristic in a tabular data form for use by the conversion mechanism.

3. The apparatus according to claim 1, wherein the ADC is included in the CPU.

4. The apparatus according to claim 1, wherein the CPU performs both the calculation mechanism of the electric potential ratio and the conversion mechanism of the electric potential ratio to the temperature.

5. A disk memory device, comprising:
a CPU for controlling operations in the device;
a spindle motor (SPM) for rotating at least one disk medium having a plurality of data tracks;
a head mechanism for holding a read/write head on the data recording tracks of the at least one disk medium;
a voice coil motor (VCM) for driving the head mechanism by angular rotation;
a head control circuit for providing read/write control signals to the head from the CPU; and
a temperature detecting circuit for detecting environmental temperature in the device for deciding an appropriate condition for providing the read/write control signals to the head;
the temperature detecting circuit, comprising:
a first voltage source dividing circuit connected to a voltage source in series, the first voltage source dividing circuit includes a first and a second elements having temperature-independent resistances;
a second voltage source dividing circuit connected to the voltage source in series, the second voltage source dividing circuit includes a third element having temperature-independent resistance and a temperature detecting element having temperature-dependent resistance;
an analog-to-digital converter for reading a digital value of a first electric potential at a first connecting point between the first and the second elements in the first voltage source dividing circuit and a second electric potential at a second connecting point between the third element and the temperature detecting element in the second voltage source dividing circuit
a calculation mechanism for calculating an electric potential ratio using the digital values detected by the ADC based on the first and the second electric potentials; and
an electric potential ratio/temperature converting mechanism for acquiring a temperature that corresponds to the electric potential ratio by referencing to a predetermined electric potential ratio-temperature characteristic.

6. The disk memory device according to claim 5, further comprising:
a first non-volatile memory for preliminary storing an electric potential ratio-temperature conversion table that shows the electric potential ratio-temperature characteristic in a tabular data form for use by the conversion mechanism.

7. The disk memory device according to claim 5, wherein the ADC is included in the CPU.

8. The disk memory device according to claim 5, wherein the CPU performs both the calculation mechanism of the electric potential ratio and the conversion mechanism of the electric potential ratio to the temperature.

9. The disk memory device according to claim 6, further comprising:
a second non-volatile memory for storing control programs for the operations in the device wherein the electric potential ratio-temperature conversion table is also stored.

10. A method for detecting temperature in an equipment that comprises a CPU for controlling operations in the equipment, a first voltage source dividing circuit including a first pair of elements connected to a voltage source in series, the first pair of elements includes a first and a second temperature-independent resistances; a second voltage source dividing circuit including a second pair of elements connected to voltage source in series, the second pair of elements includes a third element of temperature-independent resistance and a temperature detecting element of temperature-dependent resistance, comprising:
reading a first electric potential at a first connecting point positioned between the first and the second elements in the first voltage source dividing circuit and a second electric potential at a second connecting point positioned between the third element and the temperature detecting element in the second voltage source dividing circuit;
converting the first and the second electric potentials into respective digital values;
calculating an electric potential ratio between the first electric potential and the second electric potential by using the converted digital values; and
acquiring a temperature in response to the calculated electric potential ratio by referencing to a predetermined electric potential ratio-temperature characteristic.

11. The method according to claim 10, further comprising:
storing an electric potential ratio-temperature conversion table that shows the electric potential ratio-temperature characteristic in a tabular data form in a non-volatile memory.

12. The method according to claim 10, wherein both the calculating step of the electric potential ratio and the converting step of the electric potential ratio to the temperature are performed in a CPU provided for the equipment.
